(19) United States
(12) Patent Application Publication
(10) Pub. No.: US 2025/0204135 A1
(43) Pub. Date: Jun. 19, 2025

(54) DISPLAY DEVICE, METHOD FOR MANUFACTURING THE SAME, AND ELECTRONIC DEVICE INCLUDING THE SAME

(71) Applicant: SAMSUNG DISPLAY CO., LTD., YONGIN-SI (KR)

(72) Inventor: JAEWOO JEONG, Yongin-si (KR)

(21) Appl. No.: 18/978,240

(22) Filed: Dec. 12, 2024

(30) Foreign Application Priority Data
Dec. 18, 2023 (KR) 10-2023-0185241

(51) Int. Cl. H10H 29/855; H10H 29/01

(52) U.S. Cl. CPC H10H 29/8552; H10H 29/0363

(57) ABSTRACT

A display device includes a substrate having a light emitting area and a non-light emitting area. A light emitting element us disposed in the light emitting area on the substrate. A light transmission layer is disposed on the light emitting element. The light transmission layer includes a plurality of openings spaced apart from each other. The light transmission layer includes a plasma-treated surface part. A plurality of light control patterns is disposed in the plurality of openings.

### CROSS-REFERENCE TO RELATED APPLICATION

This application claims priority under 35 U.S.C. § 119 to Korean Patent Application No. 10-2023-0185241, filed on Dec. 18, 2023 in the Korean Intellectual Property Office, the disclosure of which is incorporated by reference in its entirety herein.

### 1. TECHNICAL FIELD

Embodiments of the present disclosure provide a display device and a method for manufacturing the same. More particularly, embodiments of the present disclosure relate to a display device that provides visual information and a method for manufacturing the same.

### 2. DISCUSSION OF RELATED ART

Display devices are communication media between users and information. Display devices have become increasingly important along with the development of information technology. Accordingly, consumer usage of display devices such as a liquid crystal display device, an organic light emitting display device, a plasma display device, and the like is increasing.

The display device may display an image with a wide viewing angle, or the viewing angle of the image displayed on the display device may be limited for security reasons or to reduce image reflection.

### SUMMARY

Embodiments provide a display device that can effectively control a viewing angle. Embodiments provide a method for manufacturing the display device.

According to an embodiment of the present disclosure, a display device includes a substrate having a light emitting area and a non-light emitting area. A light emitting element is disposed in the light emitting area on the substrate. A light transmission layer is disposed on the light emitting element. The light transmission layer includes a plurality of openings spaced apart from each other. The light transmission layer includes a plasma-treated surface part. A plurality of light control patterns is disposed in the plurality of openings.

In an embodiment, each of the plurality of light control patterns may have a trapezoidal shape in a cross-section having a width that decreases as a distance from the light emitting element increases.

In an embodiment, the plurality of light control patterns may include an organic material containing at least one material selected from a group consisting of black pigment and black dye.

In an embodiment, the plasma-treated surface part may include nitrogen (N₂).

In an embodiment, for a same etching process, an upper part of the light transmission layer including the plasma-treated surface part may have a first etch rate and a lower part of the light transmission layer that does not include the upper part may have a second etch rate different from the first etch rate.

In an embodiment, the first etch rate may be less than the second etch rate.

In an embodiment, the plurality of light control patterns may be spaced apart from each other in a first direction and each of the plurality of light control patterns may extend longitudinally in a second direction intersecting the first direction.

In an embodiment, the light transmission layer may include a transparent organic material.

In an embodiment, the plurality of light control patterns may overlap the light emitting area and the non-light emitting area.

In an embodiment, the plurality of light control patterns may not overlap the light emitting area and may overlap the non-light emitting area.

According to an embodiment of the present disclosure, a method for manufacturing a display device includes forming a light emitting element in a light emitting area on a substrate. An organic layer is formed on the light emitting element. A plasma-treated surface party is formed by plasma treating a surface of the organic layer. A light transmission layer is formed on the light emitting element by patterning the organic layer. The light transmission layer includes a plurality of openings spaced apart from each other. A plurality of light control patterns is formed in the plurality of opening.

In an embodiment, before the forming of the light transmission layer, the display device may further include forming a hard mask layer on the organic layer. Photosensitive organic patterns are formed on the hard mask layer. The organic layer and the hard mask layer are simultaneously patterned using the photosensitive organic patterns as mask.

In an embodiment, the plasma treating the surface of the organic layer may be performed before the forming of the hard mask layer.

In an embodiment, the plasma treating the surface of the organic layer may be performed after the forming the hard mask layer.

In an embodiment, the plasma-treated surface part may include nitrogen (N₂).

In an embodiment, the plasma treating the surface of the organic layer may be performed through an ion implantation process or a dry plasma treatment.

In an embodiment, for a same etching process, an upper part of the light transmission layer including the plasma-treated surface part may have a first etch rate and a lower part of the light transmission layer that does not include the upper part may have a second etch rate different from the first etch rate.

In an embodiment, the first etch rate may be less than the second etch rate.

In an embodiment, the plurality of light control patterns may include an organic material containing at least one material selected from a group consisting of black pigment and black dye.

In an embodiment, in the forming of the light transmission layer, the organic layer may be patterned through a dry etching process.

According to an embodiment of the present disclosure, a display device includes a light emitting element disposed on a substrate. A light transmission layer is disposed on the light emitting element. The light transmission layer includes a plurality of openings spaced apart from each other. A plurality of light control patterns is disposed in the plurality of openings. Each of the plurality of light control patterns has a trapezoidal shape in a cross-section having a width that decreases as a distance from the light emitting element increases.

In an embodiment, an upper surface of each of the plurality of light control patterns is concave.

In an embodiment, an encapsulation layer is disposed on the light emitting element. A touch sensing layer is disposed between the light emitting element and the light transmission layer.

In an embodiment, the plurality of light control patterns include an organic material containing at least one material selected from a group consisting of black pigment and black dye. The light transmission layer includes a transparent organic material.

According to an embodiment of the present disclosure, an electronic device includes a display device and a processor which controls the display device, the display device include a substrate including a light emitting area and a non-light emitting area, a light emitting element disposed in the light emitting area on the substrate, a light transmission layer disposed on the light emitting element, the light transmission layer including a plurality of openings spaced apart from each other, the light transmission layer including a plasma-treated surface part, and a plurality of light control patterns disposed in the plurality of openings

A display device according to an embodiment of the present disclosure may include a light transmission layer disposed on a light emitting element, defining a plurality of openings spaced apart from each other, and including a plasma-treated surface part, and a plurality of light control patterns each filling the plurality of openings. Here, each of the plurality of light control patterns may have a trapezoidal shape in a cross-section having a width that decreases as a distance from the light emitting element increases. Accordingly, the light efficiency of the display device may be increased. In addition, the display device may control the viewing angle more effectively.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is an enlarged plan view of a part of a display area of the display device of FIG. 1 according to an embodiment of the present disclosure.

FIG. 3 is a cross-sectional view taken along line I-I′ of FIG. 2 according to an embodiment of the present disclosure.

FIG. 4 is a plan view illustrating an example of the light control patterns of FIG. 3 according to an embodiment of the present disclosure.

FIG. 5 is a cross-sectional view illustrating the light control patterns and the light transmission layer of FIG. 3 according to an embodiment of the present disclosure.

FIGS. 6, 7, 8, 9, 10, 11, 12, 13, and 14 are cross-sectional views illustrating some steps of a method for manufacturing the display device of FIG. 3 according to embodiments of the present disclosure.

FIG. 15 is a plan view illustrating an example of the light control patterns of FIG. 3 according to an embodiment of the present disclosure.

FIG. 16 is a cross-sectional view illustrating a display device according to an embodiment of the present disclosure.

FIG. 17 is a view schematically illustrating a car according to an embodiment of the present disclosure.

FIG. 18 is a view illustrating the interior of the car of FIG. 17 according to an embodiment of the present disclosure.

FIG. 19 is a block diagram illustrating an electronic device according to an embodiment of the present disclosure.

### DETAILED DESCRIPTION OF EMBODIMENTS

Hereinafter, a display device and a method for manufacturing the same according to embodiments of the present disclosure will be explained in detail with reference to the accompanying drawings. The same reference numerals are used for the same components in the drawings, and redundant descriptions of the same components may be omitted for economy of explanation.

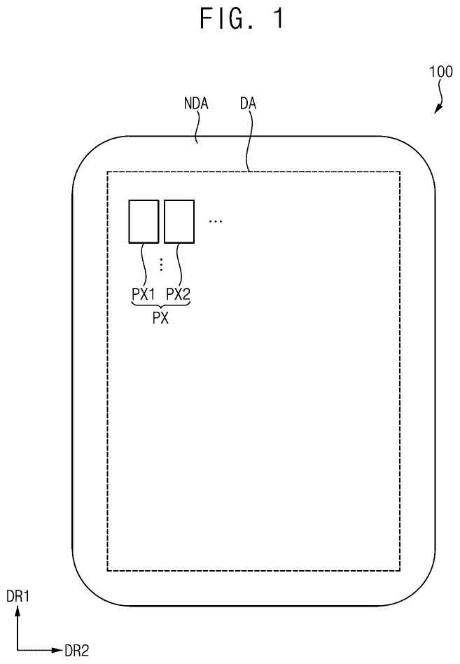

FIG. 1 is a plan view illustrating a display device according to an embodiment of the present disclosure.

Referring to FIG. 1, the display device 100 according to an embodiment of the present invention may include a display area DA and a non-display area NDA surrounding the display area DA (e.g., in the first and/or second directions DR1, DR2).

A plurality of pixels PX may be arranged in the display area DA. Each of the plurality of pixels PX may emit light. In an embodiment, the plurality of pixels PX may include a first pixel PX1 and a second pixel PX2. While two pixels of the plurality of pixels PX are shown for convenience of explanation, embodiments of the present disclosure are not necessarily limited thereto and the number of the plurality of pixels PX may vary. For example, the first pixel PX1 and the second pixel PX2 may emit light at the same time as each other. Alternatively, when the first pixel PX1 emits light, the second pixel PX2 may not emit light. Alternatively, when the first pixel PX1 does not emit light, the second pixel PX2 may emit light. As each of the plurality of pixels PX emits light, the display area DA may display an image.

The plurality of pixels PX may be repeatedly arranged along a first direction DR1 and a second direction DR2 intersecting the first direction DR1 in a plan view. For example, the second pixel PX2 may be adjacent to the first pixel PX1. In an embodiment, the second pixel PX2 may be adjacent to (e.g., immediately adjacent thereto) the first pixel PX1 in the second direction DR2.

The non-display area NDA may be located around the display area DA. For example, the non-display area NDA may surround at least a portion of the display area DA (e.g., in the first and/or second directions DR1, DR2). A driver may be disposed in the non-display area NDA. The driver may provide signals and/or voltages to the plurality of pixels PX. For example, in an embodiment the driver may include a data driver, a gate driver, and the like. The non-display area NDA may not display image.

In this specification, a plane may be defined in the first direction DR1 and the second direction DR2. For example, the first direction DR1 may be perpendicular to the second direction DR2. However, embodiments of the present disclosure are not necessarily limited thereto and the first and second directions DR1, DR2 may intersect each other at various different angles.

In an embodiment of the present disclosure, the display device 100 may include an organic light emitting display device (OLED), a liquid crystal display device (LCD), a field emission display device (FED), a plasma display device (PDP), an electrophoretic display device (EPD), or an inorganic light emitting display device (ILED). However, embodiments of the present disclosure are not necessarily limited thereto.

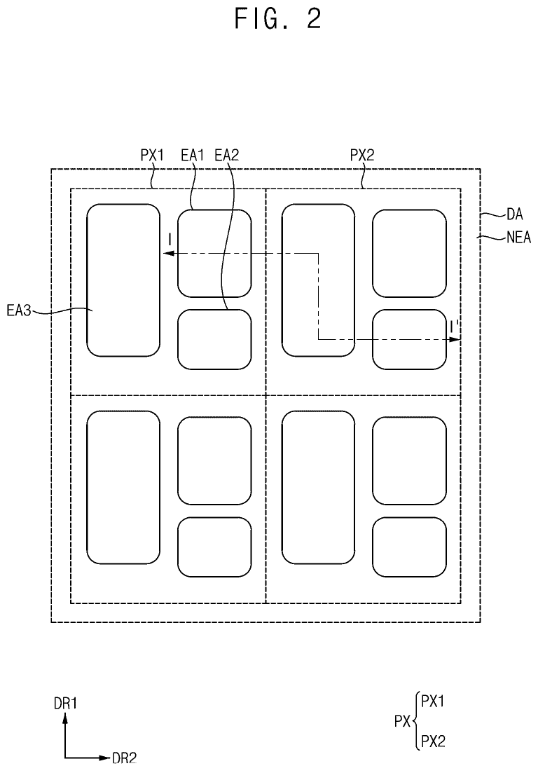

FIG. 2 is an enlarged plan view of a portion of a display area of the display device of FIG. 1.

Referring to FIGS. 1 and 2, as described above, the display device 100 may include the display area DA and the non-display area NDA, and the plurality of pixels PX may be disposed in the display area DA. In an embodiment, the plurality of pixels PX may include the first pixel PX1 and the second pixel PX2.

In an embodiment, each of the first pixel PX1 and the second pixel PX2 may include a first light emitting area EA1, a second light emitting area EA2, a third light emitting area EA3, and a non-light emitting area NEA.

The first light emitting area EA1 may emit light of a first color, the second light emitting area EA2 may emit light of a second color, and the third light emitting area EA3 may emit light of a third color. The first to third colors may be different from each other. In an embodiment, the first color may be red, the second color may be green, and the third color may be blue. As the first color light, the second color light, and the third color light are combined, each of the first pixel PX1 and the second pixel PX2 may emit light of various colors. However, embodiments of the present disclosure are not necessarily limited thereto and the colors of the first to third light emitting areas EA1 to EA3 may vary. The non-light emitting area NEA may not emit light.

The area of the first light emitting area EA1 (e.g., in a plane defined in the first and second directions DR1, DR2) may be different from the area of the second light emitting area EA2 and the third light emitting area EA3, respectively (e.g., in planes defined in the first and second directions DR1, DR2). For example, in an embodiment the area of the third light emitting area EA3 may be larger than the area of the first light emitting area EA1, and the area of the first light emitting area EA1 may be larger than the area of the second light emitting area EA2. However, embodiments of the present disclosure are not necessarily limited thereto.

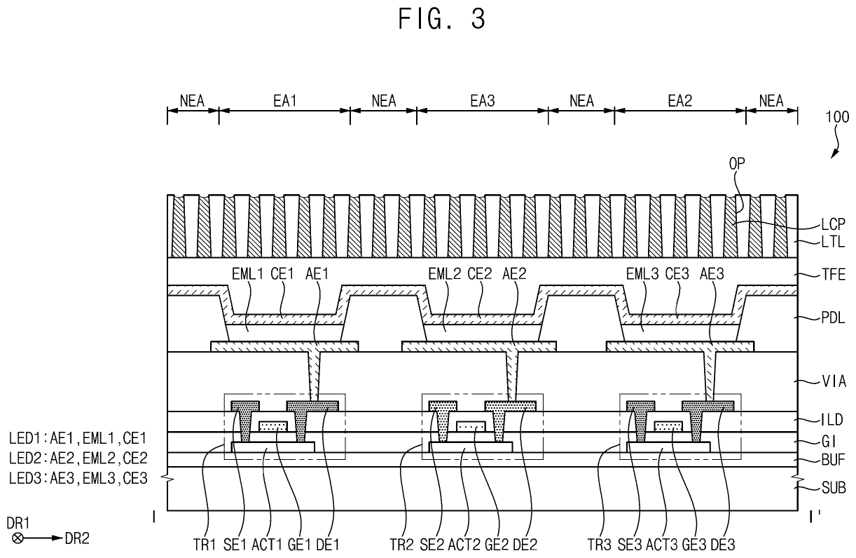

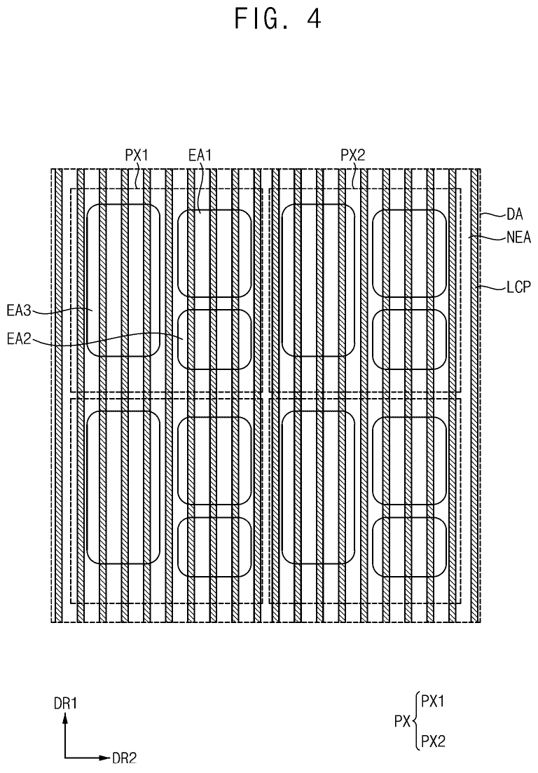

FIG. 3 is a cross-sectional view taken along line I-I′ of FIG. 2. FIG. 4 is a plan view illustrating an example of the light control patterns of FIG. 3. FIG. 5 is a cross-sectional view illustrating the light control patterns and the light transmission layer of FIG. 3.

Referring to FIG. 3, the display device 100 according to an embodiment of the present disclosure may include a substrate SUB, a buffer layer BUF, first, second, and third transistors TR1, TR2, and TR3, a gate insulation. layer GI, an interlayer insulating layer ILD, a via insulating layer VIA, a pixel defining layer PDL, first, second, and third light emitting elements LED1, LED2, and LED3, an encapsulation layer TFE, a plurality of light control patterns LCP, and a light transmission layer LTL.

In an embodiment, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

In addition, in an embodiment the first light emitting element LED1 may include a first pixel electrode AE1, a first light emitting layer EML1, and a first common electrode CE1, the second light emitting element LED2 may include a second pixel electrode AE2, a second light-emitting layer EML2, and a second common electrode CE2, and the third light emitting element LED3 may include a third pixel electrode AE3, a third light emitting layer EML3, and a third common electrode CE3.

The substrate SUB may include a transparent material or an opaque material. For example, in an embodiment the substrate SUB may be made of a transparent resin substrate. Examples of the transparent resin substrate may include a polyimide substrate. In this embodiment, the polyimide substrate may include a first organic layer, a first barrier layer, a second organic layer, and the like. Alternatively, the substrate SUB may include a quartz substrate, synthetic quartz substrate, calcium fluoride substrate, F-doped quartz substrate, a soda-lime a glass substrate, a non-alkali glass substrate, and the like. These can be used alone or in combination with each other.

The buffer layer BUF may be disposed on the substrate SUB (e.g., disposed directly thereon in a vertical direction). The buffer layer BUF may prevent metal atoms or impurities from diffusing from the substrate SUB to the first, second, and third transistors TR1, TR2, and TR3. In addition, the buffer layer BUF may increase the flatness of the surface of the substrate SUB when the surface of the substrate SUB is not uniform. For example, in an embodiment the buffer layer BUF may include an inorganic material such as silicon oxide, silicon nitride, silicon oxynitride, and the like. These materials can be used alone or in combination with each other.

The first, second, and third active patterns ACT1, ACT2, and ACT3 may be disposed on the buffer layer BUF (e.g., disposed directly thereon in the vertical direction). In an embodiment, each of the first, second, and third active patterns ACT1, ACT2, and ACT3 may include a metal oxide semiconductor, an inorganic semiconductor (e.g., amorphous silicon, poly silicon), or an organic semiconductor. Each of the first, second, and third active patterns ACT1, ACT2, and ACT3 may include a source region, a drain region, and a channel region located between the source region and the drain region. In an embodiment, the first, second, and third active patterns ACT1, ACT2, and ACT3 may be formed through the same process and may include the same material as each other.

In an embodiment, the metal oxide semiconductor may include a binary compound (ABₓ), a ternary compound (ABₓC_{y}), a quaternary compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, in an embodiment the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and the like. These materials can be used alone or in combination with each other.

The gate insulating layer GI may be disposed on the buffer layer BUF (e.g., disposed directly thereon in the vertical direction). In an embodiment, the gate insulating layer GI may sufficiently cover the first, second, and third active patterns ACT1, ACT2, and ACT3, and may have a substantially flat upper surface without creating a step around the first, second, and third active patterns ACT1, ACT2, and ACT3. Alternatively, the gate insulating layer GI may cover the first, second, and third active patterns ACT1, ACT2, and ACT3, and may be disposed along the profile of each of the first, second, and third active patterns ACT1, ACT2, and ACT3 with a uniform thickness. For example, in an embodiment the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These materials can be used alone or in combination with each other.

The first, second, and third gate electrodes GE1, GE2, and GE3 may be disposed on the gate insulating layer GI (e.g., disposed directly thereon in the vertical direction). The first gate electrode GE1 may overlap the channel area of the first active pattern ACT1 (e.g., in the vertical direction), the second gate electrode GE2 may overlap the channel area of the second active pattern ACT2 (e.g., in the vertical direction), and the third gate electrode GE3 may overlap the channel area of the third active pattern ACT3 (e.g., in the vertical direction).

In an embodiment, each of the first, second, and third gate electrodes GE1, GE2, and GE3 may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide indium zinc oxide, and the like. In addition, examples of the metal nitride may include aluminum nitride (AlNₓ), tungsten nitride (WNₓ), chromium nitride (CrNₓ), and the like. These materials can be used alone or in combination with each other.

In an embodiment, the first, second, and third gate electrodes GE1, GE2, and GE3 may be formed through the same process and may include the same material as each other.

The interlayer insulating layer ILD may be disposed on the gate insulating layer GI (e.g., disposed directly thereon in the vertical direction). In an embodiment, the interlayer insulating layer ILD may sufficiently cover the first, second, and third gate electrodes GE1, GE2, and GE3 and may have a substantially flat upper surface without creating steps around the first, second, and third gate electrodes GE1, GE2, and GE3. Alternatively, the interlayer insulating layer ILD may cover the first, second, and third gate electrodes GE1, GE2, and GE3 and may be disposed along the profile of each of the first, second, and third gate electrodes GE1, GE2, and GE3 with a uniform thickness. For example, in an embodiment the interlayer insulating layer ILD may include an inorganic material such as silicon oxide, silicon nitride, silicon carbide, silicon oxynitride, silicon oxycarbide, and the like. These materials can be used alone or in combination with each other.

The first, second, and third source electrodes SE1, SE2, and SE3 may be disposed on the interlayer insulating layer ILD (e.g., disposed directly thereon in the vertical direction). In an embodiment, the first source electrode SE1 may be connected to (e.g., directly connected thereto) the source region of the first active pattern ACT1 through a contact hole penetrating the gate insulating layer GI and the interlayer insulating layer ILD. The second source electrode SE2 may be connected to (e.g., directly connected thereto) the source region of the second active pattern ACT2 through a contact hole penetrating the gate insulating layer GI and the interlayer insulating layer ILD. The third source electrode SE3 may be connected to (e.g., directly connected thereto) the source region of the third active pattern ACT3 through a contact hole penetrating the gate insulating layer GI and the interlayer insulating layer ILD.

The first, second, and third drain electrodes DE1, DE2, and DE3 may be disposed on the interlayer insulating layer ILD (e.g., disposed directly thereon in the vertical direction). In an embodiment, the first drain electrode DE1 may be connected to (e.g., directly connected thereto) the drain region of the first active pattern ACT1 through a contact hole penetrating the gate insulating layer GI and the interlayer insulating layer ILD. The second drain electrode DE2 may be connected to (e.g., directly connected thereto) the drain region of the second active pattern ACT2 through a contact hole penetrating the gate insulating layer GI and the interlayer insulating layer ILD. The third drain electrode DE3 may be connected to (e.g., directly connected thereto) the drain region of the third active pattern ACT3 through a contact hole penetrating the gate insulating layer GI and the interlayer insulating layer ILD.

For example, in an embodiment each of the first, second, and third source electrodes SE1, SE2, and SE3 may include metal, alloy, metal nitride, conductive metal oxide, transparent conductive material, and the like. These materials can be used alone or in combination with each other. In an embodiment, the first, second, and third drain electrodes DE1, DE2, and DE3 may be formed through the same process as the first, second, and third source electrodes SE1, SE2, and SE3, and may include the same material as the first, second, and third source electrodes SE1, SE2, and SE3.

Accordingly, the first transistor TR1 including the first active pattern ACT1, the first gate electrode GE1, the first source electrode SE1, and the first drain electrode DE1 may be disposed on the substrate SUB, the second transistor TR2 including the second active pattern ACT2, the second gate electrode GE2, the second source electrode SE2, and the second drain electrode DE2 may be disposed on the substrate SUB, and the third transistor TR3 including the third active pattern ACT3, the third gate electrode GE3, the third source electrode SE3, and the third drain electrode DE3 may be disposed on the substrate SUB.

The via insulating layer VIA may be disposed on the interlayer insulating layer ILD (e.g., disposed directly thereon in the third direction D3). The via insulating layer VIA may sufficiently cover the first, second, and third source electrodes SE1, SE2, and SE3 and the first, second, and third drain electrodes DE1, DE2, and DE3. The via insulating layer VIA may include an organic material. For example, in an embodiment the via insulating layer VIA may include an organic material such as phenolic resin, polyacrylates resin, polyimides resin, polyamides resin, siloxane resin, epoxy resin, and the like. These materials can be used alone or in combination with each other.

The first, second, and third pixel electrodes AE1, AE2, and AE3 may be disposed on the via insulating layer VIA (e.g., disposed directly thereon in the vertical direction). The first pixel electrodes AE1 may be disposed in the first light emitting area EA1, the second pixel electrode AE2 may be disposed in the third light emitting area EA3, and the third pixel electrode AE3 may be disposed in the second light emitting are EA2. In an embodiment, the first pixel electrode AE1 may be connected to (e.g., directly connected thereto) the first drain electrode DE1 through a contact hole penetrating the via insulating layer VIA, the second pixel electrode AE2 may be connected to (e.g., directly connected thereto) the first drain electrode DE2 through a contact hole penetrating the via insulating layer VIA. In addition, the third pixel electrode AE3 may be connected to (e.g., directly connected thereto) the third drain electrode DE3 through a contact hole penetrating the via insulating layer VIA.

For example, in an embodiment each of the first, second, and third pixel electrodes AE1, AE2, and AE3 may include metal, alloy, metal nitride, conductive metal oxide, transparent conductive material, and the like. These materials can be used alone or in combination with each other. In an embodiment, each of the first, second, and third pixel electrodes AE1, AE2, and AE3 may have a stacked structure including ITO/Ag/ITO. In an embodiment, the first, second, and third pixel electrodes AE1, AE2, and AE3 may be formed through the same process and may include the same material from each other. For example, each of the first, second, and third pixel electrodes AE1, AE2, and AE3 may operate as an anode.

The pixel defining layer PDL may be disposed on the via insulating layer VIA (e.g., disposed directly thereon in the vertical direction). The pixel defining layer PDL may overlap the non-light emitting area NEA (e.g., in the vertical direction). In an embodiment, the pixel defining layer PDL may cover the lateral edges of each of the first, second, and third pixel electrodes AE1, AE2, and AE3. In addition, an opening exposing a portion of the upper surface of each of the first, second, and third pixel electrodes AE1, AE2, and AE3 may be defined in the pixel defining layer PDL. For example, in an embodiment the opening may expose a central portion (e.g., in the second direction DR2) of the upper surface of each of the first to third pixel electrodes AE1 to AE3. For example, in an embodiment the pixel defining layer PDL may be an inorganic material. In an embodiment, the pixel defining layer PDL may include an organic material such as an epoxy resin, a siloxane resin, and the like. These materials may be used alone or in combination with each other. However, embodiments of the present disclosure are not necessarily limited thereto. For example, in an embodiment, the pixel defining layer PDL may include an inorganic material and/or an organic material containing a light blocking material such as black pigment, black dye, and the like.

The first light emitting layer EML1 may be disposed on the first pixel electrode AE1 (e.g., in the vertical direction), the second light emitting layer EML2 may be disposed on the second pixel electrode AE2 (e.g., in the vertical direction). In addition, the third light emitting layer EML3 may be disposed on the third pixel electrode AE3 (e.g., in the vertical direction). Each of the first, second, and third light emitting layers EML1, EML2, and EML3 may include a light emitting material that emits light of a preset color. For example, in an embodiment the first light emitting layer EML1 may include a light emitting material that emits red light, the second light emitting layer EML2 may include a light emitting material that emits blue light, and the third light emitting layer EML3 may include a light emitting material that emits green light. However, embodiments of the present disclosure are not necessarily limited thereto and the colors emitted by the first to third light emitting layers EM1 to EML3 may vary.

The first common electrode CE1 may be disposed on the first light emitting layer EML1 and the pixel defining layer PDL, the second common electrode CE2 may be disposed on the second light emitting layer EML2 and the pixel defining layer PDL. In addition, the third common electrode CE3 may be disposed on the third light emitting layer EML3 and the pixel defining layer PDL. In an embodiment, the first, second, and third common electrodes CE1, CE2, and CE3 may be formed integrally. However, embodiments of the present disclosure are not necessarily limited thereto. For example, each of the first, second, and third common electrodes CE1, CE2, and CE3 may include metal, alloy, metal nitride, conductive metal oxide, transparent conductive material, and the like. These materials can be used alone or in combination with each other. The first, second, and third common electrodes CE1, CE2, and CE3 may operate as cathode.

Accordingly, the first light emitting element LED1 including the first pixel electrode AE1, the first light emitting layer EML1, and the first common electrode CE1 may be disposed in the first light emitting area EA1 on the substrate SUB, the second light emitting element LED2 including the second pixel electrode AE2, the second light emitting layer EML2, and the second common electrode CE2 may be disposed in the third light emitting area EA3 on the substrate SUB, and the third light emitting element LED3 including the third pixel electrode AE3, the third light emitting layer EML3, and the third common electrode CE3 may be disposed in the second light emitting area EA2 on the substrate SUB.

In an embodiment, the first light emitting element LED1 may be electrically connected to the first transistor TR1, the second light emitting element LED2 may be electrically connected to the second transistor TR2, and the third light emitting element LED3 may be electrically connected to the third transistor TR3.

The encapsulation layer TFE may be disposed on the first, second, and third common electrodes CE1, CE2, and CE3 (e.g., disposed directly thereon in the vertical direction). The encapsulation layer TFE may prevent impurities, moisture, external air, and the like from penetrating into the first, second, and third light emitting elements LED1, LED2, and LED3 from the outside (e.g., the external environment). In an embodiment, the encapsulation layer TFE may include at least one inorganic layer and at least one organic layer. For example, in an embodiment the inorganic layer may include silicon oxide, silicon nitride, silicon oxynitride, and the like. These materials can be used alone or in combination with each other. The organic layer may include a cured polymer such as polyacrylate.

The light transmission layer LTL may be disposed on the encapsulation layer TFE (e.g., disposed directly thereon in the vertical direction). Light emitted from the first, second, and third light emitting elements LED1, LED2, and LED3 may pass through the light transmission layer LTL. In an embodiment, the light transmission layer LTL may have a substantially flat upper surface. In an embodiment, the light transmission layer LTL may include a transparent organic material. For example, in an embodiment the light transmission layer LTL may include a transparent organic material such as epoxy resin, siloxane resin, polyimide resin, photoresist, and the like. These materials can be used alone or in combination with each other.

In an embodiment, a plurality of openings OP spaced apart from each other may be defined in the light transmission layer LTL. In an embodiment, the plurality of openings OP may be spaced apart from each other along the second direction DR2. However, embodiments of the present disclosure are not necessarily limited thereto.

In an embodiment, each of the plurality of openings OP may have a trapezoidal shape in a cross-section in which a width of the opening OP (e.g., length in the second direction DR2) decreases as a distance (e.g., in the vertical direction) from the first, second, and third light emitting elements LED1, LED2, and LED3 increases. In this embodiment, a part of the light transmission layer LTL located between two adjacent openings OP may have an inverse taper shape (e.g., a trapezoidal shape having a width that increases as a distance from the first, second, and third light emitting elements LED1, LED2, and LED3 increases) in a cross-section.

In an embodiment, the light transmission layer LTL may include a plasma-treated surface part SP. In an embodiment, the plasma-treated surface part SP may be disposed on an upper surface of the light transmission layer LTL. For example, in an embodiment the plasma-treated surface part SP may include nitrogen (N₂). However, embodiments of the present disclosure are not necessarily limited to this, and the plasma-treated surface part SP may include various different plasma gases.

In an embodiment, as the light transmission layer LTL includes the plasma-treated surface part SP, surface modification such as carbon-carbon bonding may occur on the surface of the light transmission layer LTL. Accordingly, for the same etching process, an upper part UP including the surface part SP of the light transmission layer LTL may have a first etch rate, and a lower part LP excluding the upper part UP of the light transmission layer LTL may have a second etch rate different from the first etch rate.

In an embodiment, the first etch rate may be less than the second etch rate. As the first etch rate is less than the second etch rate, each of the plurality of openings OP may have a trapezoidal shape in a cross-section having a width that decreases as a distance from the first, second, and third light emitting elements LED1, LED2, and LED3 increases.

The plurality of light control patterns LCP spaced apart from each other may be disposed on the encapsulation layer TFE (e.g., disposed directly thereon in the vertical direction). The plurality of light control patterns LCP may be surrounded by the light transmission layer LTL. In an embodiment, the plurality of light control patterns LCP may fill the plurality of openings OP, respectively. In an embodiment, the plurality of light control patterns LCP may overlap the non-light emitting area NEA and the first, second, and third light emitting areas EA1, EA2, and EA3. However, embodiments of the present disclosure are not necessarily limited thereto.

In an embodiment, each of the plurality of light control patterns LCP may include an organic material containing a light blocking material, such as at least one material selected from a group consisting of black pigment and black dye. However, embodiments of the present disclosure are not necessarily limited thereto.

Light emitted from the first, second, and third light emitting elements LED1, LED2, and LED3 may be incident on the light control patterns LCP or may pass through the light transmission layer LTL between the light control patterns LCP. Light incident on the light control patterns LCP may be reflected from the light control patterns LCP, transmitted by the light control patterns LCP, or absorbed by the light control patterns LCP. For example, in an embodiment, most of the light incident on the light control patterns LCP may be absorbed by the light control patterns LCP. Accordingly, the light control patterns LCP may control the viewing angle of the display device 100.

For example, in an embodiment in which the display device 100 is a front emitting type, the light control patterns LCP may be disposed above the first, second, and third light emitting elements LED1, LED2, and LED3 (e.g., in the vertical direction). Alternatively, when the display device 100 is a bottom emitting type, the light control patterns LCP may be disposed under the first, second, and third light emitting elements LED1, LED2, and LED3 (e.g., in the vertical direction).

In an embodiment, the light control patterns LCP may be spaced apart from each other in the second direction DR2, and each of the light control patterns LCP may extend longitudinally in the first direction DR1 (see FIG. 4). However, embodiments of the present disclosure are not necessarily limited thereto.

In an embodiment, each of the light control patterns LCP may have a cross-sectional shape having a width that decreases as the distance from the first, second, and third light emitting elements LED1, LED2, and LED3 increases. For example, in this embodiment, an angle θ formed between the side surfaces of each of the light control patterns LCP and the upper surface of the encapsulation layer TFE may be an acute angle. Here, the angle θ refers to the smaller angle among the angles formed between the side surfaces of each of the light control patterns LCP and the upper surface of the encapsulation layer TFE.

For example, in an embodiment an upper surface US of each of the plurality of light control patterns LCP may have a concave shape. For example, with respect to the substrate SUB, the upper surface US of each of the plurality of light control patterns LCP may be located at a lower level (e.g., in the vertical direction) than an upper surface of the light transmission layer LTL (see FIG. 5). Thus, in an embodiment the light control patterns LCP may not completely fill an uppermost surface of the opening OP and may fill the remaining portions of the opening OP. However, embodiments of the present disclosure are not necessarily limited thereto.

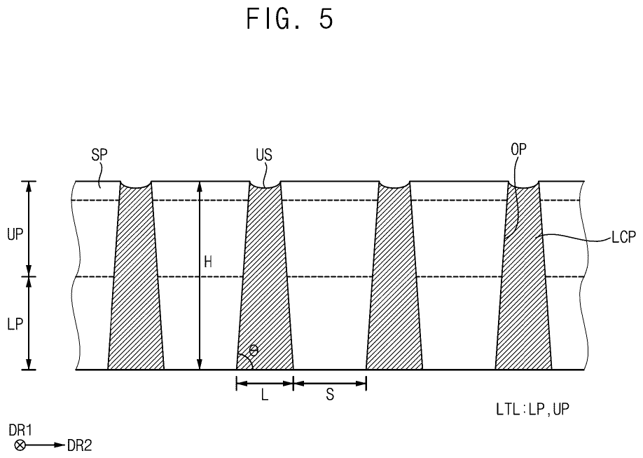

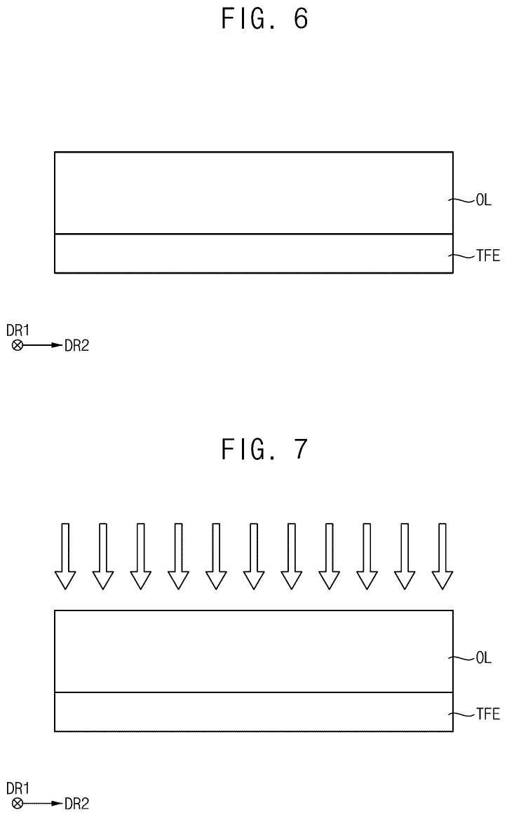

FIGS. 6, 7, 8, 9, 10, 11, 12, 13, and 14 are cross-sectional views illustrating some steps of a method for manufacturing the display device of FIG. 3. Hereinafter, descriptions that overlap with the description of the display device 100 described with reference to FIG. 3 may be omitted or simplified for economy of explanation.

Referring to FIGS. 3 and 6, in an embodiment the buffer layer BUF, the first, second, and third active patterns ACT1, ACT2, and ACT3, the gate insulating layer GI, the first, second, and third gate electrodes GE1, GE2, and GE3, the interlayer insulating layer ILD, the first, second, and third source electrodes SE1, SE2, and SE3, the first, second, and third drain electrodes DE1, DE2, and DE3, the via insulating layer VIA, the first, second, and third pixel electrodes AE1, AE2, and AE3, the pixel defining layer PDL, the first, second, and third light emitting layers EML1, EML2, and EML3, the first, second, and third common electrode CE1, CE2, and CE3, and the encapsulation layer TFE may be sequentially formed on the substrate SUB.

In an embodiment, an organic layer OL may be formed on the encapsulation layer TFE (e.g., formed directly thereon in the vertical direction). For example, the organic layer OL may be formed using transparent organic materials such as epoxy resin, siloxane resin, polyimide resin, photoresist, and the like.

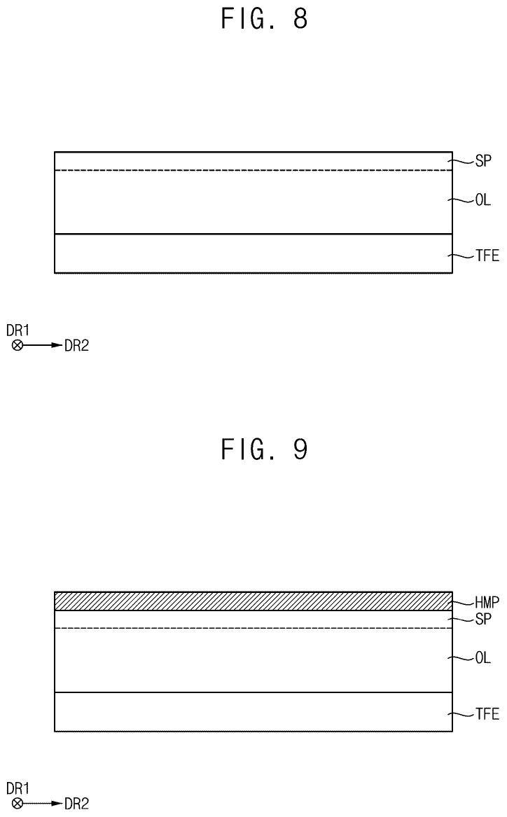

Referring to FIGS. 7 and 8, in an embodiment, the surface of the organic layer OL (e.g., an upper surface thereof in the vertical direction) may be plasma treated. Accordingly, the organic layer OL may include the plasma-treated surface part SP on an upper surface thereof (e.g., in the vertical direction). For example, in an embodiment the plasma-treated surface part SP of the organic layer OL may include nitrogen (N₂). However, embodiments of the present disclosure are not necessarily limited thereto.

In an embodiment, the plasma treating the surface of the organic layer OL may be performed through an ion implantation process or a dry plasma treatment.

In an embodiment, the plasma treating the surface of the organic layer OL may be performed before forming a hard mask layer HML, which will be described later. However, embodiments of the present disclosure are not necessarily limited thereto, and the plasma treating the surface of the organic layer OL may be performed after forming the hard mask layer HML, which will be described later.

Referring to FIG. 9, the hard mask layer HML may be formed on the organic layer OL. For example, in an embodiment the hard mask layer HML may be formed directly on an upper surface of the plasma-treated surface part SP. In an embodiment, the hard mask layer HML may be formed using a metal material. For example, in an embodiment the hard mask layer HML may be formed using a transparent oxide such as indium tin oxide (ITO), indium zinc oxide (IZO), and the like. However, embodiments of the present disclosure are not necessarily limited thereto.

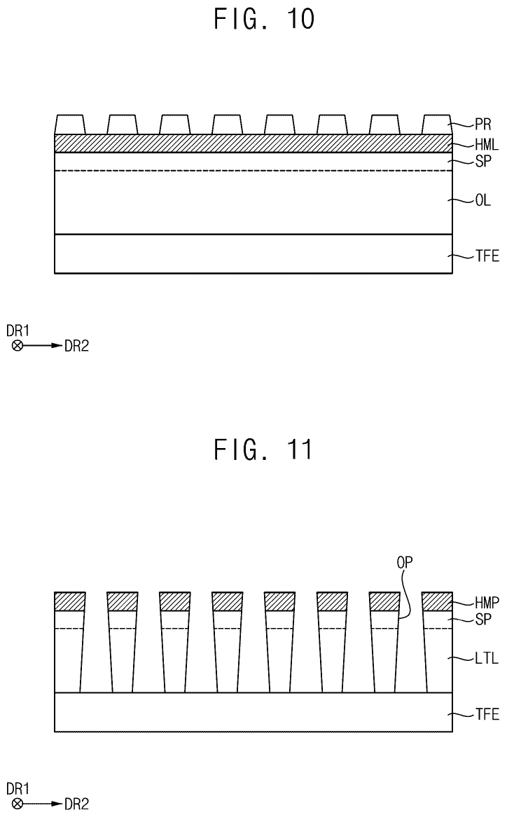

Referring to FIG. 10, photosensitive organic patterns PR may be formed on the hard mask layer HML. For example, in an embodiment the photosensitive organic patterns PR may be formed directly on an upper surface of the hard mask layer HML. In an embodiment, the photosensitive organic patterns PR may be formed using a positive photoresist. Alternatively, photosensitive organic patterns PR may be formed using negative photoresist.

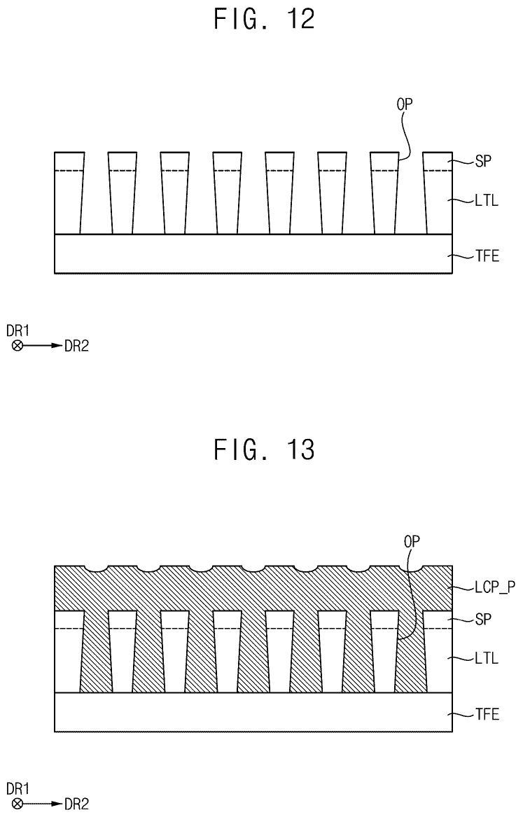

Referring to FIG. 11, in an embodiment the organic layer OL and the hard mask layer HML may be patterned simultaneously by irradiating light to the organic layer OL and the hard mask layer HML using the photosensitive organic patterns PR as a mask. In this embodiment, a part of the organic layer OL and a part of the hard mask layer HML that do not overlap the photosensitive organic patterns PR may be removed. In an embodiment, the organic layer OL and the hard mask layer HML may be patterned through a dry etching process.

Accordingly, in an embodiment the light transmission layer LTL including the plasma-treated surface part SP and defining the plurality of openings OP spaced apart from each other (e.g., in the second direction DR2), and a plurality of hard mask patterns HMP on the light transmission layer LTL may be formed. In an embodiment, after the light transmission layer LTL and the plurality of hard mask patterns HMP are formed, the photosensitive organic patterns PR may be removed.

Referring to FIG. 12, after the photosensitive organic patterns PR are removed, a plurality of hard mask patterns HMP may be removed. For example, the plurality of hard mask patterns HMP may be removed through a dry etching process.

Referring to FIG. 13, a preliminary light control pattern LCP_P may be formed on (e.g., formed directly thereon) the light transmission layer LTL. The preliminary light control pattern LCP_P may be formed by filling the plurality of openings OP of the light transmission layer LTL. For example, the preliminary light control pattern LCP_P may be formed using an organic material containing a light-blocking material such as black pigment, black dye, and the like. In an embodiment, an upper surface of the preliminary light control pattern LCP_P may have a concave shape in portions overlapping the opening (e.g., in the vertical direction).

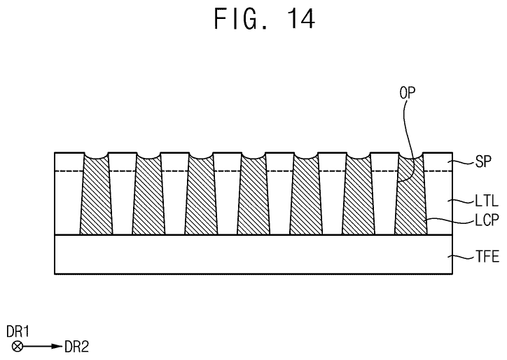

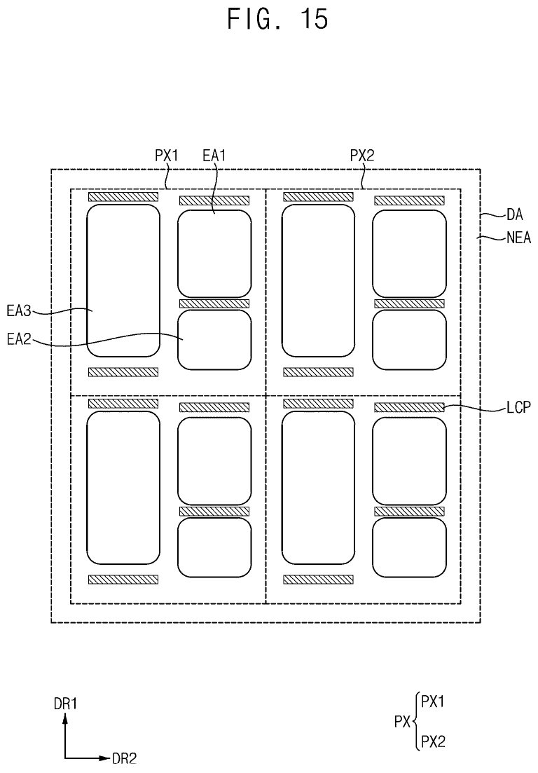

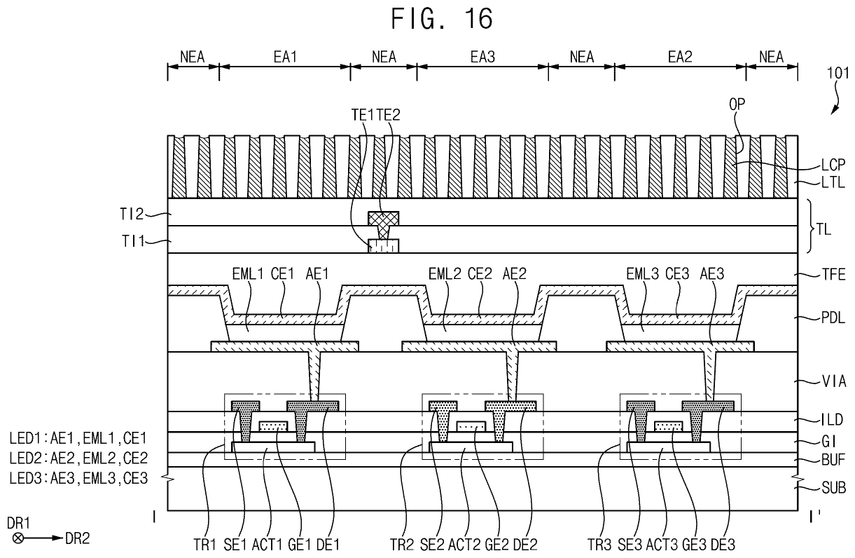

Referring further to FIG. 14, a part of an upper part of the preliminary light control pattern LCP_P may be removed. For example, in an embodiment the part of the upper part of the preliminary light control pattern LCP_P may be removed through a chemical mechanical polishing (CMP) process. Accordingly, the plurality of light control patterns LCP may be formed to each fill the plurality of openings OP. An upper surface US of each of the plurality of light control patterns LCP may have a concave shape similar to the removed portions of the upper surface of the preliminary light control pattern LCP_P in the portions overlapping the opening OP as shown in FIG. 13.

Hereinafter, the effects of embodiments of the present disclosure according to Comparative Examples and Embodiments will be described.

In Comparative Example 1 and Comparative Example 2, a light transmission layer including a polyimide resin was formed on an encapsulation layer, and a plurality of light control patterns surrounded by the light transmission layer, spaced apart from each other, and including a known black matrix material were formed. The plurality of light control patterns do not have the trapezoidal shape in a cross-section. A width L of each of the plurality of light control patterns, a distance S between the plurality of adjacent light control patterns, a height H of each of the plurality of light control patterns, and the angle θ between the side surface of each of the plurality of light control patterns and the encapsulation layer is shown in Table 1 below.

In Embodiment 1 and Embodiment 2, the light transmission layer LTL including a polyimide resin was formed on the encapsulation layer TFE, and the plurality of light control patterns LCP surrounded by the light transmission layer LTL, spaced apart from each other, and including a known black matrix material were formed. The width L of each of the plurality of light control patterns LCP, the distance S between the plurality of adjacent light control patterns LCP, the height H of each of the plurality of light control patterns LCP, and the angle θ between the side surface of each of the plurality of light control patterns LCP and the encapsulation layer TFE is shown in Table 1 below.

TABLE 1

| | | | Comparative | Comparative |
|---|---|---|---|---|
| | Embodiment 1 | Embodiment 2 | Example 1 | Example 2 |
| Width L | 4 μm | 12 μm | 4 μm | 12 μm |
| Distance S | 13 μm | 39 μm | 13 μm | 39 μm |
| Height H | 35 μm | 105 μm | 35 μm | 105 μm |
| Angle θ | 87.5 degrees | 87.5 degrees | 90 degrees | 90 degrees |

Light efficiency and cut-off characteristic of the display device including the plurality of light control patterns and the light transmission layer satisfying Comparative Example 1 and Comparative Example 2 were measured. In addition, the light efficiency and cut-off characteristic of the display device 100 including the plurality of light control patterns LCP and the light transmission layer LTL satisfying Embodiment 1 and Embodiment 2 were measured. Here, “light efficiency” refers to the light transmittance of the display device from the front, and “cut-off characteristic” refers to the light transmittance of the display device at a viewing angle of approximately 35 degrees based on a thickness direction of the display device.

As a result, referring to Table 2 below, it can be confirmed that the light efficiency of the display device 100 satisfying Embodiment 1 and Embodiment 2 is higher than the light efficiency of the display device satisfying Comparative Example 1 and Comparative Example 2. In addition, it can be confirmed that the cut-off characteristic of the display device 100 satisfying Embodiment 1 and Embodiment 2 are decreased compared to the cut-off characteristic of the display device satisfying Comparative Example 1 and Comparative Example 2.

TABLE 2

| | Embodiment | Embodiment | Comparative | Comparative |
|---|---|---|---|---|
| | 1 | 2 | Example 1 | Example 2 |
| Light | 88.5 | 91.0 | 75.6 | 75.0 |
| efficiency (%) | | | | |
| Cut-off | 2.6 | 2.6 | 4.3 | 4.4 |
| characteristic | | | | |
| (%) | | | | |

Through this, it can be confirmed that as each of the plurality of light control patterns LCP has a trapezoidal shape in a cross-section having a width that decreases as a distance from a light emitting element (e.g., the first, second, and third light emitting elements LED1, LED2, and LED3 of FIG. 3) increases, the light efficiency of the display device 100 is relatively high and the cut-off characteristic of the display device 100 is relatively decreased. Here, decreasing the cut-off characteristic of the display device 100 refers to that the value of the cut-off characteristic of the display device 100 is relatively small.

FIG. 15 is a plan view illustrating an embodiment of the light control patterns of FIG. 3.

Referring to FIG. 15, in an embodiment, the plurality of light control patterns LCP may overlap the non-light emitting area NEA and may not overlap the first, second, and third light emitting areas EA1, EA2, and EA3.

FIG. 16 is a cross-sectional view illustrating a display device according to an embodiment of the present disclosure.

Referring to FIG. 16, a display device 101 according to an embodiment of the present disclosure may include a substrate SUB, a buffer layer BUF, first, second, and third transistors TR1, TR2, and TR3, a gate insulation layer GI, an interlayer insulating layer ILD, a via insulating layer VIA, a pixel defining layer PDL, first, second, and third light emitting elements LED1, LED2, and LED3, an encapsulation layer TFE, a touch sensing layer TL, a plurality of light control patterns LCP, and a light transmission layer LTL.

However, the display device 101 described with reference to FIG. 16 may be substantially the same as or similar to the display device 100 described with reference to FIG. 3 except that it further includes the touch sensing layer TL. Therefore, hereinafter, overlapping descriptions may be omitted or simplified for economy of explanation.

The touch sensing layer TL may be disposed on the encapsulation layer TFE. For example, in an embodiment the touch sensing layer TL may be disposed directly on the encapsulation layer TFE (e.g., in the vertical direction). In an embodiment, the touch sensing layer TL may be disposed between the encapsulation layer TFE and the light transmission layer LTL (e.g., in the vertical direction).

In an embodiment, the touch sensing layer TL may include a first touch electrode TE1, a first touch insulating layer TI1 disposed on the first touch electrode TE1, a second touch electrode TE2 disposed on the first touch insulating layer TI1, and a second touch insulating layer TI2 disposed on the second touch electrode TE2. In an embodiment, the second touch insulating layer TI2 may have a substantially flat upper surface. The second touch electrode TE2 may be connected to (e.g., directly connected thereto) the first touch electrode TE1 through a contact hole penetrating the first touch insulating layer TI1. The touch sensing layer TL may function as an input means of the display device 101.

The display device 100 and 101 according to an embodiment of the present disclosure may include the light transmission layer LTL disposed on the first, second, and third light emitting element LED1, LED2, and LED3, defining the plurality of openings OP spaced apart from each other, and including the plasma-treated surface part SP, and the plurality of light control patterns LCP each filling the plurality of openings OP. In an embodiment, each of the plurality of light control patterns LCP may have a trapezoidal shape in a cross-section having a width that decreases as a distance from the first, second, and third light emitting element LED1, LED2, and LED3 increases. Accordingly, the light efficiency of the display device 100 and 101 may be increased. In addition, the display device 100 and 101 may control the viewing angle more effectively.

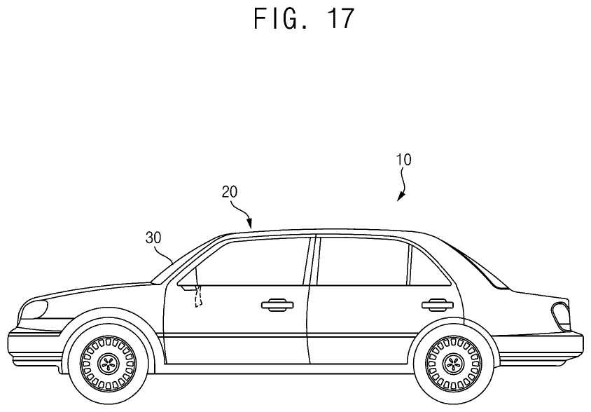

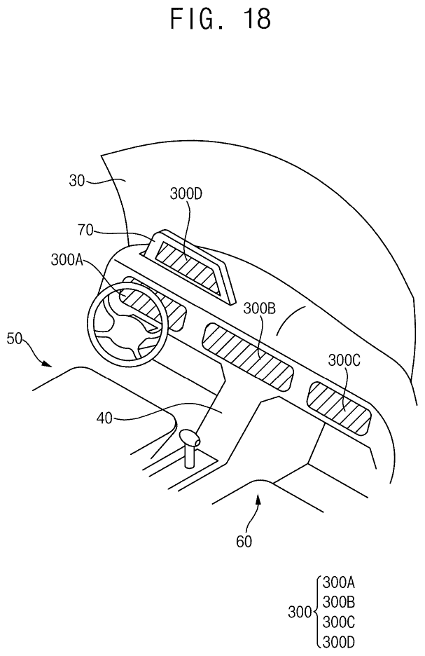

FIG. 17 is a view schematically illustrating a vehicle. FIG. 18 is a view illustrating an inside of the vehicle of FIG. 17.

Referring to FIGS. 17 and 18, in an embodiment a vehicle 10 may include a vehicle body 20 and a vehicle display device 300. The vehicle body 20 may form the exterior of the vehicle 10 and may define an indoor space in which a driver and a passenger ride. The vehicle body 20 may include a windshield 30 that protects the driver and passenger from the outside and provides the driver with a view. The vehicle display device 300 may be disposed in the indoor space. The vehicle display device 300 may have substantially the same structure as the display device 100 of FIG. 3 or the display device 101 of FIG. 16.

In an embodiment, the vehicle display device 300 may include first, second, third, and fourth display areas 300A, 300B, 300C, and 300D that are spaced apart from each other. For example, in an embodiment the first, second, and third display areas 300A, 300B, and 300C may be disposed on the dashboard 40 provided in the indoor space. For example, the first display area 300A may be disposed on the dashboard 40 in front of the driver's seat 50 to provide speed information and the like to the driver, and the second display area 300B may be disposed in the center of the dashboard 40 to provide map information and the like. In addition, the third display area 300C may be disposed on the dashboard 40 in front of the passenger seat 60 to provide entertainment information to the passenger.

In addition, the fourth display area 300D may be included in a vehicle head up display 70. The vehicle head up display 70 may be disposed on the dashboard 40. For example, the fourth display area 300D may provide the driver with information helpful for driving.

For example, in an embodiment the first, second, and third display areas 300A, 300B, and 300C may be included in one display device. In this embodiment, the fourth display area 300D may be included in a separate display device from the first, second, and third display areas 300A, 300B, and 300C. Alternatively, the first, second, third, and fourth display areas 300A, 300B, 300C, and 300D may all be included in one display device. However, embodiments of the present disclosure are not necessarily limited thereto.

The third display area 300C disposed on the dashboard 40 may adjust the viewing angle according to the mode. In an embodiment, the third display area 300C may display an image in a wide viewing angle mode or a narrow viewing angle mode. For example, the wide viewing angle mode may mean a state in which the viewing angle (e.g., the field of view) of the third display area 300C is relatively large. In the wide viewing angle mode, an image may be displayed to the driver in the driver's seat 50 as well as the passenger in a passenger's seat 60. Accordingly, both the passenger and the driver may view the image of the third display area 300C. Unlike this, the narrow viewing angle mode may mean a state in which the field of view of the third display area 300C is relatively small. In the narrow view mode, an image may be displayed only to (e.g., viewable by) the passenger in the front passenger seat 60, and may not be displayed to (e.g., viewable by) the driver in the driver's seat 50. Accordingly, only the passenger may view the image of the third display area 300C.

Although the description has been made based on the third display area 300C disposed on the dashboard 40, embodiments of the present disclosure are not necessarily limited thereto. For example, the viewing angles of the first display area 300A, the second display area 300B, and the fourth display area 300D may be adjusted according to the mode.

In addition, although it has been described that the vehicle display device 300 is disposed on the dashboard 40, embodiments of the present disclosure are not necessarily limited thereto. For example, the vehicle display device 300 may be disposed on the windshield 30 in some embodiments.

In addition, the display device 100 of FIG. 3 or the display device 101 of FIG. 16 according to embodiments of the present disclosure is not necessarily limited to being applied only to the vehicle display device 300 disposed on the vehicle 10 of FIGS. 17 and 18, and may be applied to various display devices.

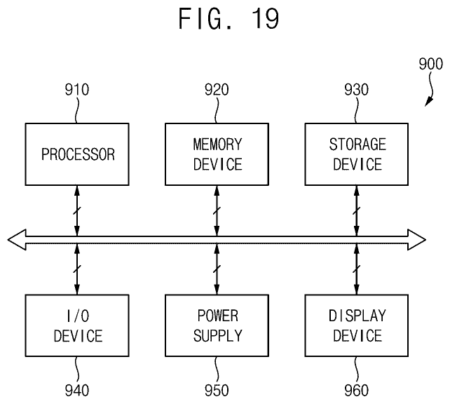

FIG. 19 is a block diagram illustrating an electronic device according to an embodiment of the present disclosure.

Referring to FIG. 19, in an embodiment, an electronic device 900 may include a processor 910, a memory device 920, a storage device 930, an input/output device 940, a power supply 950, and a display device 960. In this case, the display device 960 may correspond to the display device 100 or 101 described with reference to FIGS. 3, 16. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

Embodiments of the present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in embodiments without materially departing from the novel teachings and advantages of the present disclosure. Accordingly, all such modifications are intended to be included within the scope of the present disclosure. Therefore, it is to be understood that the foregoing is illustrative of various embodiments and is not to be construed as limited to the specific embodiments disclosed, and that modifications to the disclosed embodiments, as well as other embodiments, are intended to be included within the scope of the present disclosure.

What is claimed is:

1. A display device comprising:
a substrate including a light emitting area and a non-light emitting area;
a light emitting element disposed in the light emitting area on the substrate;
a light transmission layer disposed on the light emitting element, the light transmission layer including a plurality of openings spaced apart from each other, the light transmission layer including a plasma-treated surface part; and
a plurality of light control patterns disposed in the plurality of openings.

2. The display device of claim 1, wherein each of the plurality of light control patterns has a trapezoidal shape in a cross-section having a width that decreases as a distance from the light emitting element increases.

3. The display device of claim 1, wherein the plurality of light control patterns include an organic material containing at least one material selected from a group consisting of black pigment and black dye.

4. The display device of claim 1, wherein the plasma-treated surface part includes nitrogen (N₂).

5. The display device of claim 1, wherein for a same etching process, an upper part of the light transmission layer including the plasma-treated surface part has a first etch rate and a lower part of the light transmission layer that does not include the upper part has a second etch rate different from the first etch rate.

6. The display device of claim 5, wherein the first etch rate is less than the second etch rate.

7. The display device of claim 1, wherein the plurality of light control patterns are spaced apart from each other in a first direction and each of the plurality of light control patterns extends longitudinally in a second direction intersecting the first direction.

8. The display device of claim 1, wherein the light transmission layer includes a transparent organic material.

9. The display device of claim 1, wherein the plurality of light control patterns overlap the light emitting area and the non-light emitting area.

10. The display device of claim 1, wherein the plurality of light control patterns do not overlap the light emitting area and overlap the non-light emitting area.

11. A method for manufacturing a display device, the method comprising:
forming a light emitting element in a light emitting area on a substrate;
forming an organic layer on the light emitting element;
forming a plasma-treated surface part by plasma treating a surface of the organic layer;
forming a light transmission layer on the light emitting element by patterning the organic layer, the light transmission layer including a plurality of openings spaced apart from each other; and
forming a plurality of light control patterns in the plurality of openings.

12. The method of claim 11, before the forming of the light transmission layer, further comprising:
forming a hard mask layer on the organic layer;
forming photosensitive organic patterns on the hard mask layer; and
simultaneously patterning the organic layer and the hard mask layer using the photosensitive organic patterns as mask.

13. The method of claim 12, wherein the plasma treating the surface of the organic layer is performed before the forming of the hard mask layer.

14. The method of claim 12, wherein the plasma treating the surface of the organic layer is performed after the forming the hard mask layer.

15. The method of claim 11, wherein the plasma-treated surface part includes nitrogen (N₂).

16. The method of claim 11, wherein the plasma treating the surface of the organic layer is performed through an ion implantation process or a dry plasma treatment.

17. The method of claim 11, wherein for a same etching process, an upper part of the light transmission layer including the plasma-treated surface part has a first etch rate and a lower part of the light transmission layer that does not include the upper part has a second etch rate different from the first etch rate.

18. The method of claim 17, wherein the first etch rate is less than the second etch rate.

19. The method of claim 11, wherein the plurality of light control patterns include an organic material containing at least one material selected from a group consisting of black pigment and black dye.

20. The method of claim 11, wherein in the forming of the light transmission layer, the organic layer is patterned through a dry etching process.

21. A display device comprising:
a light emitting element disposed on a substrate;
a light transmission layer disposed on the light emitting element, the light transmission layer including a plurality of openings spaced apart from each other; and
a plurality of light control patterns disposed in the plurality of openings,
wherein each of the plurality of light control patterns has a trapezoidal shape in a cross-section having a width that decreases as a distance from the light emitting element increases.

22. The display device of claim 21, wherein:
an upper surface of each of the plurality of light control patterns is concave.

23. The display device of claim 21, wherein:
an encapsulation layer is disposed on the light emitting element; and
a touch sensing layer is disposed between the light emitting element and the light transmission layer.

24. The display device of claim 21, wherein:
the plurality of light control patterns include an organic material containing at least one material selected from a group consisting of black pigment and black dye; and
the light transmission layer includes a transparent organic material.

25. An electronic device comprising:
a display device; and
a processor which controls the display device,
wherein the display device includes:
a substrate including a light emitting area and a non-light emitting area;
a light emitting element disposed in the light emitting area on the substrate;
a light transmission layer disposed on the light emitting element, the light transmission layer including a plurality of openings spaced apart from each other, the light transmission layer including a plasma-treated surface part; and
a plurality of light control patterns disposed in the plurality of openings.
